(19) United States
(12) Patent Application Publication
(10) Pub. No.: US 2006/0175708 A1
(43) Pub. Date: Aug. 10, 2006

(54) Semiconductor device and method of manufacturing the same

(75) Inventor: Kazuyoshi Ueno, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/350,834

(22) Filed: Feb. 10, 2006

(30) Foreign Application Priority Data
Feb. 10, 2005 (JP) 2005-035162

(51) Int. Cl. H01L 23/52; H01L 21/4763

(52) U.S. Cl. 257/774; 438/629; 257/762; 257/758

(57) ABSTRACT

A nitrided metal cap film 35 is provided in the upper portion of the metal cap 34 including CoWP. The metal cap 34 and the nitrided metal cap film 35 can be, for example, 1 nm to 100 nm in layer thickness. A ratio of the layer thickness of the nitrided metal cap layer 35 to that of the metal cap 34 can be, for example, 0.1 to 1. Moreover, an SiOCN layer 16 obtained by nitriding the surface of an SiOC layer 14a is formed on the SiOC layer 14a. The SiOCN layer 16 is a layer including a region in which nitrogen is segregated on the surface, and can be, for example, 1 nm to 100 nm in thickness.

This application is based on Japanese Patent application NO. 2005-035162, the content of which is incorporated hereinto by reference.

### BACKGROUND

1. Technical Field

The present invention relates to a structure of a semiconductor device and a method of manufacturing the semiconductor device, and, more particularly, to a copper interconnect line which has a metal cap film on the surface.

2. Related Art

Recently, copper has been more widely used as an interconnect material in a situation in which a higher-speed semiconductor device is required. Copper has a lower resistance and a lower capacitance in comparison with those of an aluminum interconnect line, which has been used so far, and is superior in resistance to electromigration and to stress migration. On the other hand, copper has a property of being easily oxidized even at a low temperature of 150° C. in an atmosphere including oxygen. Thereby, a technology by which the copper surface is coated with an oxidation barrier film has been generally used in a process for forming a copper interconnect line. A silicon nitride film, a silicon carbide film, and the like, which can be deposited by chemical vapor growth without using oxygen, are used as a barrier film against oxidation and Cu diffusion. However, these oxidation barrier films have a high dielectric constant (the dielectric constant of the silicon nitride film is 8, and that of the silicon carbide film is 5) to cause increase in a parasitic capacitance between interconnects.

A technology, by which a metal cap film is selectively provided by electroless plating on the surface of a copper interconnect line, has been known as a solution of the above problems. For example, there has been a proposal according to which a CoWP film is selectively formed on the surface of a copper interconnect line to protect the surface of copper, which is easily oxidized, by coating with CoWP and, thereafter, an insulating layer such as oxide silicon, which is grown in an oxidizing atmosphere, is deposited.

However, the above technology has had the following problems. That is, when cleaning is processed with hydrofluoric acid, and the like in order to remove copper and cobalt atoms, which remain on the surface of the insulating layer between interconnects, the CoWP film is etched and damaged, and, in extreme cases, the CoWP film might disappear. The reason is that CoWP is eroded with a cleaning liquid such as hydrofluoric acid. Moreover, CoWP is more hardly oxidized in comparison with copper, and, when CoWP is exposed to the chemical-vapor-growth atmosphere forming oxide silicon, CoWP is oxidized to form a cobalt oxide, and to increase connecting resistance of a via in some cases.

Accordingly, a technology, by which the CoWP film is coated with a cobalt silicide layer with resistance to oxidation, and to hydrofluoric acid, has been proposed as disclosed in Laid-open patent publication No. 2002-43315. In this technology, as shown in FIG. 6, a lower copper interconnect line 2, an upper copper interconnect line 3, and a copper via 4 are formed in an interlayer 1 between interconnects, and a metal cap film 5 and a silicide layer 6 in the metal cap film are formed on the upper surface of the lower copper interconnect line 2 and on that of the upper layer copper interconnect line 3. Here, the silicide layer 6 in the metal cap film is formed by exposing the metal cap film 5 to the silane gas after forming the metal cap film 5.

However, when the surface of the insulating layer between interconnects (SiO.sub.2 and the like) is exposed to the silane gas in order to form the above-described cobalt silicide layer, there is a possibility that the surface is electrically activated by adsorption of a Si atoms through decomposition of silane leading to increase a leakage current. Moreover, as there is no etching stopper, a via hole for forming the copper via 4 reaches even the side of the lower copper interconnect line 2 in a misalignment portion when via etching is performed. Thereby, poor filling of via metal is caused.

### SUMMARY OF THE INVENTION

According to the present invention, there is provided a semiconductor device including: a semiconductor substrate; an insulating layer which has a concave (trench) portion and is provided on the semiconductor substrate; a metal layer which includes copper and is embedded in the concave (trench) portion; and a metal cap film covering the upper portion of the metal layer, wherein at least the upper portion of the metal cap film is nitrided. Here, “nitrided” means “including nitrogen”.

Moreover, the present invention provides a method of manufacturing a semiconductor device including: forming an insulating layer on a semiconductor substrate; selectively removing the insulating layer and forming a concave (trench) portion; forming a metal layer including copper in the concave (trench) portion; forming a metal cap film on the surface of the metal layer; and nitriding the surface of the metal cap film and that of the insulating layer.

According to the present invention, the reliability at a contacting (via) portion between a metal layer including copper and a metal layer provided thereon is improved, because the invention has a structure in which the upper portion of a metal cap film is nitrided.

### BRIEF DESCRIPTION OF THE DRAWINGS

The above and other objects, advantages and features of the present invention will be more apparent from the following description taken in conjunction with the accompanying drawings, in which:

FIG. 1A is a cross-sectional view of an interconnect structure according to an embodiment;

FIG. 1B is a cross-sectional view of an interconnect structure according to an embodiment;

FIG. 2A is a process chart showing a step in a method of manufacturing the interconnect structure shown in FIGS. 1A and 1B;

FIG. 2B is a process chart showing a step in the method of manufacturing the interconnect structure shown in FIGS. 1A and 1B as a continuation of FIG. 2A;

FIG. 2C is a process chart showing a step in the method of manufacturing the interconnect structure shown in FIGS. 1A and 1B as a continuation of FIG. 2B;

FIG. 2D is a process chart showing a step in the method of manufacturing the interconnect structure shown in FIGS. 1A and 1B as a continuation of FIG. 2C;

FIG. 2E is a process chart showing a step in the method of manufacturing the interconnect structure shown in FIGS. 1A and 1B as a continuation of FIG. 2D;

FIG. 2F is a process chart showing a step in the method of manufacturing the interconnect structure shown in FIGS. 1A and 1B as a continuation of FIG. 2E;

FIG. 3A is a process chart showing a step in the method of manufacturing the interconnect structure shown in FIGS. 1A and 1B as a continuation of FIG. 2F;

FIG. 3B is a process chart showing a step in the method of manufacturing the interconnect structure shown in FIGS. 1A and 1B as a continuation of FIG. 3A;

FIG. 3C is a process chart showing a step in the method of manufacturing the interconnect structure shown in FIGS. 1A and 1B as a continuation of FIG. 3B;

FIG. 3D is a process chart showing a step in the method of manufacturing the interconnect structure shown in FIGS. 1A and 1B as a continuation of FIG. 3C;

FIG. 4 is a process chart showing a step in the method of manufacturing the interconnect structure shown in FIGS. 1A and 1B;

FIG. 5 is a cross-sectional view of an interconnect structure according to an embodiment;

FIG. 6 is a cross-sectional view of a conventional interconnect structure; and

FIG. 7 is a cross-sectional view of an interconnect structure according to an embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

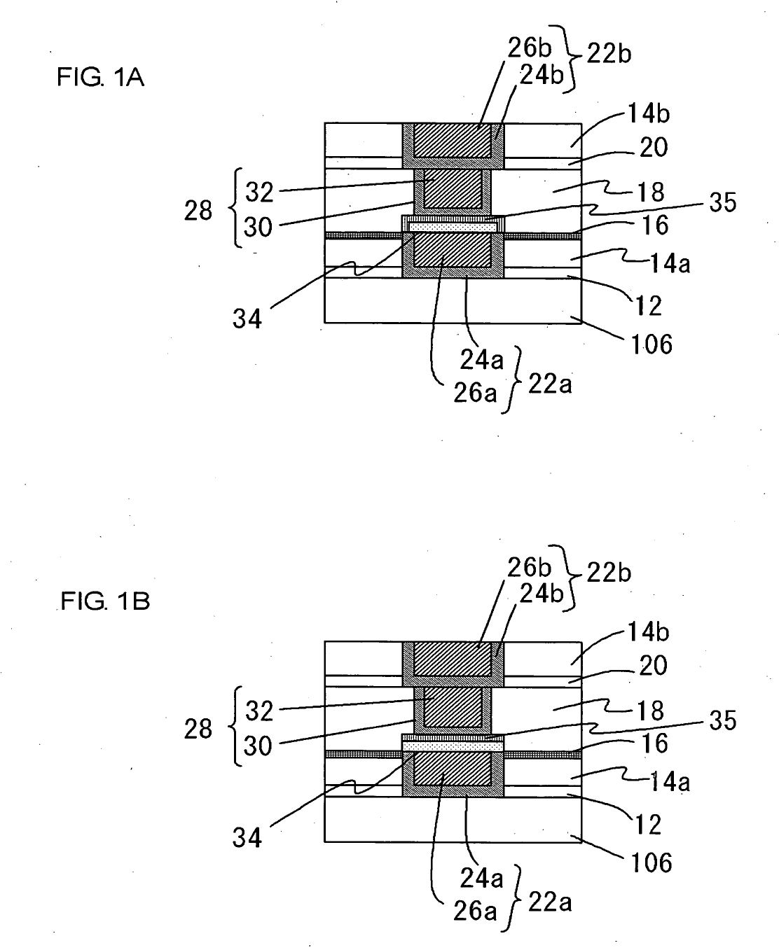

FIG. 1A is a cross-sectional view showing an interconnect structure according to the present embodiment.

A semiconductor device shown in FIG. 1A comprises:

a semiconductor substrate; an insulating layer which has a concave (trench) portion and is provided on said semiconductor substrate;

a metal film which includes copper and is embedded in said concave (trench) portion; and

a metal cap covering the upper portion of said metal film, wherein

at least the upper portion of said metal cap is nitrided.

The insulating layer has a multilayer structure including a first insulating layer and a second insulating film provided in the upper portion of said first insulating layer. The upper surface of the second insulating layer is at the same level as that of said metal. The first insulating layer is a porous film and said second insulating layer is a dense film.

Hereinafter, an interconnect structure according to the present embodiment will be explained, referring to FIG. 1A and FIG. 1B.

A nitrided metal cap film 35 is provided in the upper portion of the metal cap 34 including CoWP. The metal cap 34 and the nitrided metal cap film 35 can be, for example, 1 nm to 100 nm in layer thickness. A ratio of the layer thickness of the nitrided metal cap layer 35 to that of the metal cap 34 can be, for example, 0.1 to 1. Moreover, an SiOCN layer 16 obtained by nitriding the surface of an SiOC layer 14a is formed on the SiOC layer 14a. The SiOCN layer 16 is a layer which includes nitrogen, and can be, for example, 1 nm to 100 nm in thickness.

A SiCN layer 12, a SiOC layer 14a, a SiOCN layer 16 formed by nitriding the surface of the SiOC layer 14a, a silicon oxide layer 18, a SiCN layer 20, and a SiOC layer 14b are stacked in this order on an insulating layer 106 of a silicon substrate (not shown). A first copper interconnect line 22a is formed in the SiOC layer 14a, and a second copper interconnect line 22b is formed in the SiOC layer 14b. Here, the “SiOC layer” is a layer including Si, O, C, and H, and is formed according to a plasma CVD method using an organic silane gas, and the like. The SiOC film with a porous structure is used in this embodiment.

The first copper interconnect line 22a comprises a tantalum-based barrier metal film 24a and a copper film 26a. A connecting plug 28 connected to the upper surface of the first copper interconnect line 22a is formed in the silicon oxide layer 18. The connecting (via) plug 28 includes a tantalum-based barrier metal layer 30 and a copper layer 32. The second copper interconnect line 22b connected to the upper surface of a connecting hole is formed in the SiOC layer 14b. The second copper interconnect line 22b includes a tantalum-based barrier metal layer 24b and a copper layer 26b.

The first copper interconnect line 22a, the connecting (via) plug 28, and the second copper interconnect line 22b have approximately the same width, and form an interconnect line with a borderless contact.

A metal cap 34 is formed on the upper surface of the first copper interconnect line 22a. A constituent material of the metal cap 34 includes: a cobalt containing metal such as Co, CoWP, CoWB, CoB, and CoP; a nickel containing metal such as Ni, NiMoP, NiMoB, NiWP, NiWB, NiReP, NiReB, NiB, and NiP; a silver containing metal such as Ag and AgCu; and the like.

Here, the metal cap 34 is provided in such a way that the upper surface of the metal cap 34 is positioned higher than that of the SiOC layer 14a.

A nitrided metal cap layer 35 is formed in the upper portion of the metal cap 34. When the metal cap 34 includes, for example, CoWP, the nitrided metal cap film 35 becomes CoWPN.

The metal cap 34 and the nitrided metal cap film 35 can be, for example, 1 nm to 100 nm, preferably, 10 nm to 50 nm in layer thickness. Thereby, the resistance to stress migration can be surely improved. A ratio of the layer thickness of the nitrided metal cap film 35 to that of the metal cap 34 can be assumed to be, for example, 0.1 to 1. Thereby, stable via contact can be realized. It is assumed in the present embodiment that the layer thickness of the metal cap 34 is five nm, and that of the nitrided metal cap film 35 is five nm.

The nitrided surface of cap metal 34 has another effects, improvement of a thermal stability of the copper interconnects such as electrical resistance. Surface nitridation of the CoWP cap metal can improve its thermal stability, inhibiting resistance increase due to Co diffusion into the Cu interconnects.

The surface of the SiOC layer 14a is nitrided to form the SiOCN layer 16 on the SiOC layer 14a. The SiOCN layer 16 and the surface of the metal cap 34 have been simultaneously nitrided. The SiOCN layer 16 is a layer comprising a region which includes nitrogen, and can be, for example, 1 nm through 100 nm, preferably, 2 nm through 50 nm. As silicon precipitates on the surface of the SiOC layer 14a in a conventional technology for silane processing, it is difficult to form a nitrogen containing layer (the SiOCN layer 16) with a uniform thickness, though the nitrogen containing layer can be formed in the present embodiment. According to the present embodiment, such a layer is stably formed because the clean surface of the SiOC layer 14a is nitrided. Here, a structure, in which the nitrided metal cap film 35 is stacked on the upper surface of the metal cap 34 as shown in FIG. 1B, may be applied, though this embodiment has a structure in which the nitrided metal cap film 35 is formed as shown in FIG. 1A in such a way that the upper surface and the side of the metal cap 34 is covered.

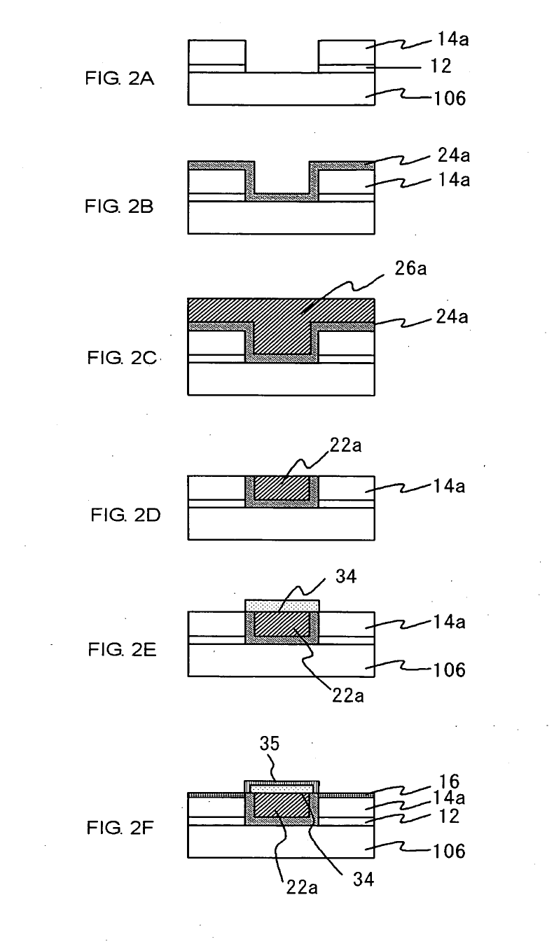

Hereinafter, a method by which an interconnect structure according to the present embodiment is manufactured will be explained, referring to FIG. 2A through FIG. 4.

FIG. 2A shows a state in which an interconnect trench is formed in the SiCN layer 12 and the SiOC layer 14a. The interconnect trench is formed according to processing in which the SiCN layer 12 and the SiOC layer 14a are formed, a resist film (not shown) with a predetermined pattern is provided on the 14a, and the SiCN layer 12 and the SiOC layer 14a are etched in steps.

Subsequently, a tantalum-based barrier metal film 24a in which Ta and TaN are stacked is formed on the whole surface of the substrate by a sputtering method (FIG. 2B). Subsequently, the copper film 26a is formed on the tantalum-based barrier metal film 24a and annealing as shown in FIG. 2C.

Then, the copper film 26a and the tantalum-based barrier metal film 24a, which have been undesirably formed on the outside of the interconnect trench are removed by chemical, mechanical polishing (CMP), and the first copper interconnect line 22a is formed in such a way that the copper film 26a and the like remain only inside the interconnect trench (FIG. 2D).

Subsequently, the metal cap 34 is formed on the surface of the first copper interconnect line 22a as shown in FIG. 2E. The metal cap 34 can be formed by electroless plating and the like. A catalyst used for electroless plating may include, for example, palladium. Moreover, the metal cap 34 can be deposited on the copper surface by electroless plating without using the palladium catalyst, which is called self-initiation process. As described above, the constituent material of the metal cap 34 is, for example, a cobalt containing metal such as CoWP, a nickel containing metal such as NiWP, and a silver containing metal such as AgCu.

The surface of the structure which has been manufactured as described above is nitrided. Thereby, the nitrided metal cap film 35 and the SiOCN layer 16 are formed as shown in FIG. 2F. A method of nitriding surfaces includes: plasma processing such as NH₃ plasma processing, N₂—H₂ plasma processing, and N₂ plasma processing; NH₃ heat-treating (thermal nitriding); N₂ ion implantation, and the like. This embodiment has adopted ammonia plasma processing.

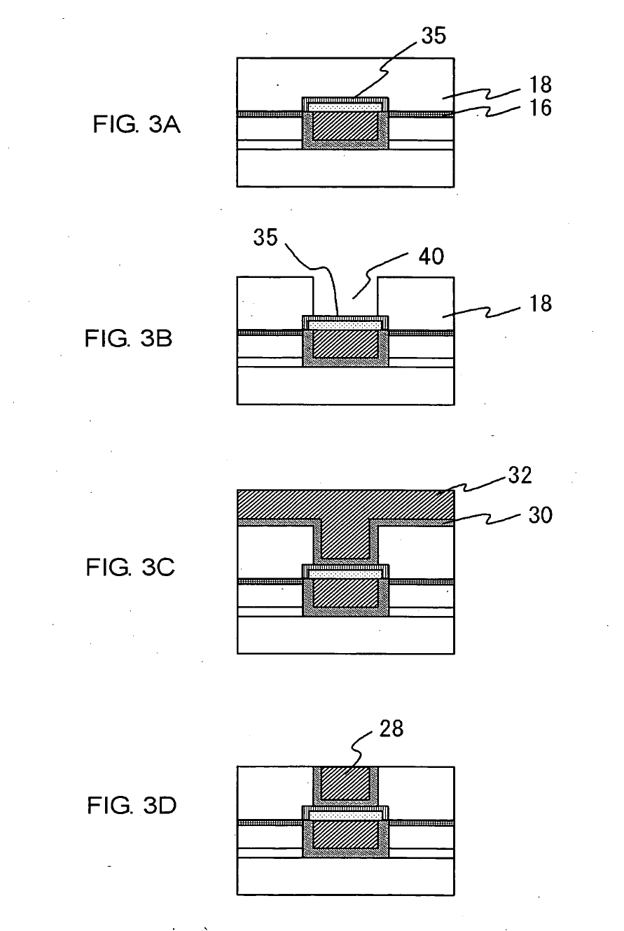

Thereafter, the silicon oxide layer 18 is formed on the nitrided metal cap film 35 and the SiOCN layer 16 as shown in FIG. 3A.

Subsequently, the silicon oxide layer 18 is selectively etched, and a connecting hole 40 is formed reaching the upper surface of the nitrided metal cap film 35 (FIG. 3B).

Thereafter, the tantalum-based barrier metal layer 30 and the copper layer 32 are formed in this order in such a way that the interior of the connecting (via) hole 40 is embedded(FIG. 3C). The copper layer 32 is formed by plating in the same manner as the copper film 26a in the first copper interconnect line 22a. Thereafter, the copper layer 32 is planarized by CMP to form the connecting (via) plug 28 (FIG. 3D).

Subsequently, the structure of the copper interconnect line shown in FIGS. 1A and 1B is formed by forming the copper interconnect line 22b on the connecting (via) plug 28 according to processes similar to the above-described ones. A metal cap and a nitrided metal cap film can be formed even in the upper portion of the copper interconnect line 22b in the same manner as the copper interconnect line 22a.

Thereafter, a semiconductor device with a multilayered structure, which has three or more layers, of interconnect lines can be formed by repeating the above-described processes.

The semiconductor device according to the present embodiment has the following advantages. In the first place, the resistance to oxidation and the copper-diffusion barrier characteristic between the copper interconnect line and the thereon are improved in the semiconductor device according to this embodiment because the semiconductor device has a structure in which the upper portion of the metal cap 34 is covered with the nitrided metal cap film 35. Here, the metal cap 34 has a structure in which the surface of the insulating layer between the interconnects is removed, and the upper surface of the metal cap is provided at a higher position than that of the SiOC layer 14a in order to decrease a leakage current between interconnects. According to the above-described structure, stable contact with the via plug can be realized. Thereby, there is obtained an advantage that stability in the contacting (via) resistance and the like are improved.

In the second place, clearance caused by misalignment at via etching is hardly generated, and poor embedding of copper into the clearance is not easily generated, because the semiconductor device according to the present embodiment is provided with the SiOCN layer 16 with a function as an etching stopper. Thereby, incomplete manufacturing and degradation of reliability, which are caused by the clearance, can be prevented. Here, as the SiOCN layer 16 is a layer obtained by nitriding of the surface of the SiOC layer 14a, increase in the dielectric constant of the insulating layer between interconnects can be more controlled to contribute to decrease in crosstalk between interconnects, in comparison with a conventional case in which a nitrided layer is provided as a diffusion barrier.

In the third place, as the surface of the SiOC layer 14a is nitrided to form the SiOCN layer 16, the surface of the insulating layer between interconnects is inactivated by nitrogen, and the leakage current can be reduced. Different from the above-described conventional technology in which silane processing of the metal cap is performed, the surface of the insulating layer between interconnects is not required to be exposed to silane gas, and there is generated no leakage current caused by Si atoms which have been generated by decomposition of silane and have adhered to the surface of the insulating layer between interconnects. Here, the SiOC layer 14a comprises a porous material in this embodiment. Accordingly, plasma penetrates into the layer during nitriding plasma processing to promote nitriding, and the SiOCN layer 16 with a desired thickness can be formed in a stable manner.

The embodiments according to the present invention have been described above, referring to the drawings. But, the above embodiments are to be considered as illustrative and not restrictive, and the present invention can adopt various kinds of configurations, except the above embodiments.

For example, the whole metal cap 34 may be nitrided by nitriding processing to form a nitrided layer though the above-described embodiments have a structure in which the upper portion of the metal cap 34 is covered with the nitrided metal cap film 35. Moreover, the upper surface of the metal cap may be provided at a lower position than that of the SiOC layer 14a though the above embodiments have a structure in which the upper surface of the metal cap is provided at a higher position than that of the SiOC layer 14a. Furthermore, an example in which the metal cap 34 is formed so that the cap 34 is extended even to portions other than the surface of the first copper interconnect line 22a, and covers a part of the surface of the SiOC layer 14a may be adopted though the above embodiments have shown an example in which the metal cap 34 is selectively formed only on the surface of the first copper interconnect line 22a.

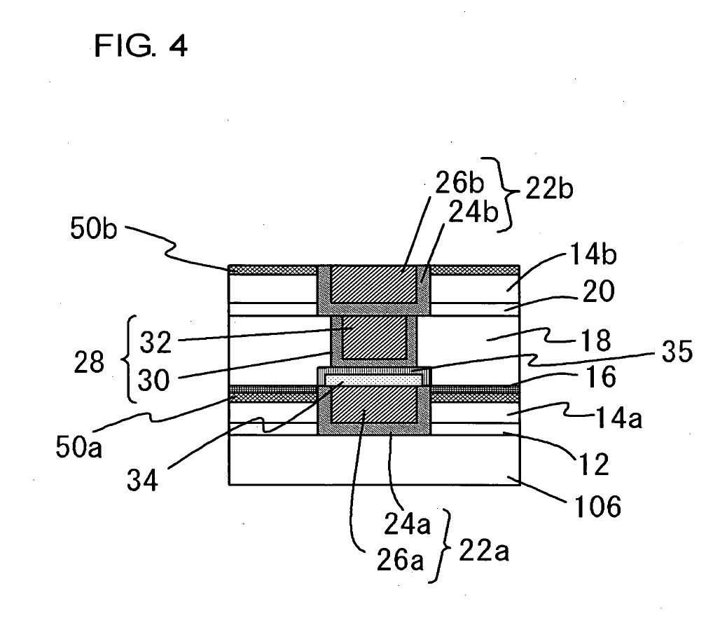

Moreover, a two-layer structure as shown in FIG. 4 may be adopted, though this embodiment has a structure in which the insulating layer between interconnects (a layer formed in a region between the level of the lower surface and that of the upper surface of the copper interconnect line 22a) is constituted by the porous SiOC layer 14a.

The insulating layer between interconnects can be formed by another insulating film. The upper portion of the insulating layer can be preferably constituted by a water-repellent (hydrophobic) insulating material. Thereby, current leakages can be eliminated. The water-repellent (hydrophobic)insulating material is, for example, SiOC, Fluorine content Polymer, poly aril ether (PAE), porous SiOC, or porous PAE.

As shown in FIG. 4, the insulating layer between interconnects in the copper interconnect line 22a has a structure in which the porous SiOC layer 14a and an SiOC layer 50a with a dense (non-porous) structure provided thereon are stacked. According to the above structures, reduction in the dielectric constant of the insulating layer between interconnects can be realized, compared with all dense SiOC structure, and, at the same time, the mechanical strength of the surface of the insulating layer between interconnects can be increased to improve CMP resistance and the like, compared with all porous SiOC structure.

Moreover, a two-layer structure as shown in FIG. 4 may be adopted, though this embodiment has a structure in which the insulating layer between interconnects (a layer formed in a region between the level of the lower surface and that of the upper surface of the copper interconnect line 22a) is constituted by the porous SiOC layer 14a.

An SiC film, an SiCN film, or an SiOC film can be formed over the nitrided metal cap film 35 and the SiOCN layer 16, though this embodiment has a structure in which a silicon oxide layer 18 is formed over the nitrided metal cap film 35 and the SiOCN layer 16.

Though an example in which copper is used as an interconnect material has been shown in the present embodiment, other metal materials may be used. For example, a copper alloy including a dissimilar metal such as silver and aluminum may be applied.

Moreover, in the insulating layer between interconnects, a coated film of methyl silsesquioxane (MSQ) and the like, or an organic film of an aromatic hydrocarbon compound and the like may be used though the above embodiments have used a CVD-SiOC film.

Moreover, the present invention can be applied to an interconnect structure formed by dual damascene processing though the above embodiments have described an interconnect structure formed by single damascene processing as an example.

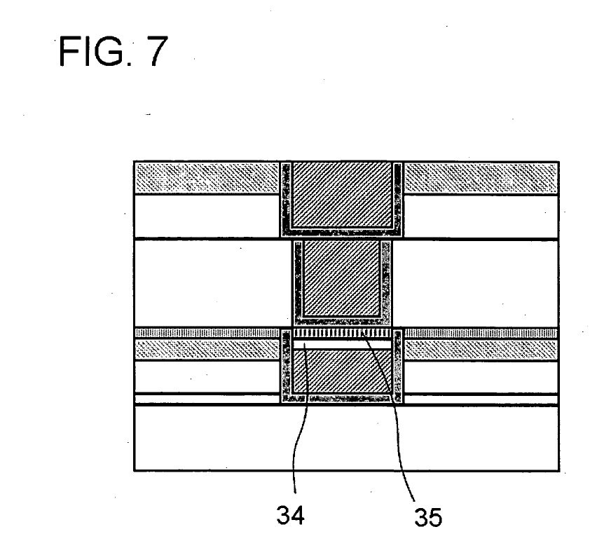

Moreover, both of the metal cap 34 and the nitrided metal cap 35 can be embedded in the trench as shown in the FIG. 7.

The present invention can be applied to an interconnect structure in which copper is embedded in the concave. The concave can be a trench or a hole. Though an example in which copper is embedded in the trench has been shown in the present embodiment, copper can be embedded in the hole.

### EXAMPLE 1

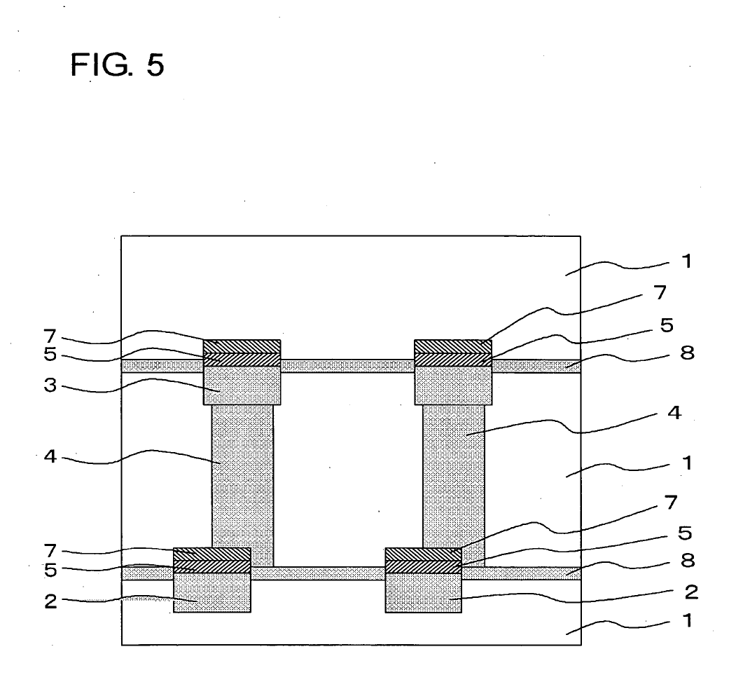

FIG. 5 shows a view showing a structure of a semiconductor device according to the present example. A lower copper interconnect line 2, an upper layer copper interconnect line 3, and a copper via 4 are formed in an interlayer 1 between interconnects. A metal cap film 5 and a nitrided layer 7 in the metal cap film are formed on the upper surface of the lower copper interconnect line 2 and that of the upper layer copper interconnect line 3. A nitrided layer 8 in the interlayer between interconnects is formed at the boundary between layers in the interlayer 1 between interconnects.

In this example, CoWP has been used as the metal cap film. The metal cap film has been set at 100 nm, and the nitrided layer 8 in the interlayer between interconnects has been set at 50 nm in layer thickness. NH₃ plasma processing has been used as a method of forming the nitride layer 7 in the metal cap film and the nitrided layer 8 in the interlayer between interconnects.

According to this example, the resistance to oxidation and the copper-diffused barrier characteristic of the metal cap film 5 can be improved by forming the nitride layer 7 in the metal cap film 5 on the metal cap film 5. Moreover, there is no worry that the surface of the SiOC film is electrically activated by adsorption of Si atoms through decomposition of silane leading to increase a leakage current, because the nitrided layer 7 in the metal cap film is not required to be exposed to silane gas when the nitrided layer 7 is formed.

Furthermore, the leakage current can be reduced because the nitrided layer 8 in the interlayer between interconnects is formed and the surface of the insulating layer between interconnects is inactivated (passivated) by nitrogen.

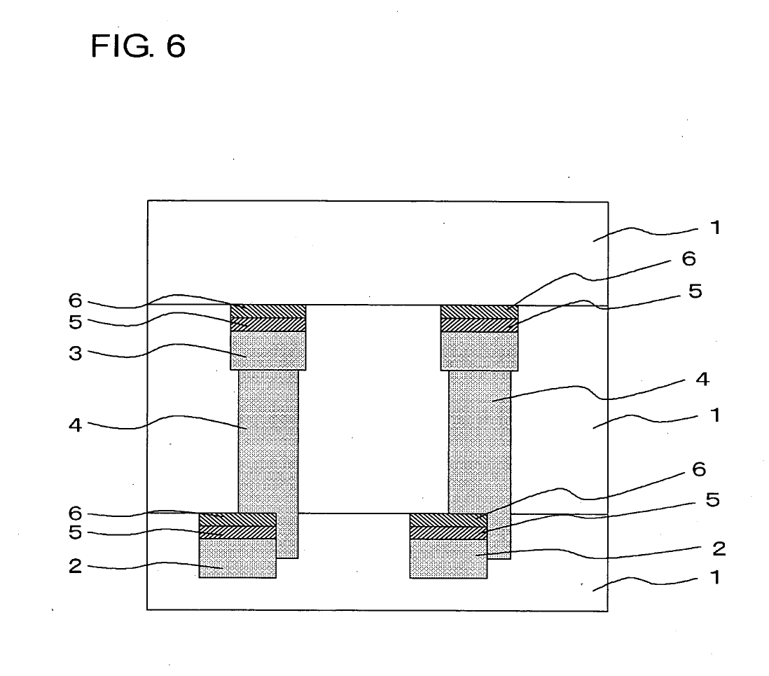

Moreover, clearance caused by misalignment at via etching is hardly generated, and poor filling of copper into the clearance is not easily generated, because the nitrided layer 8 in the interlayer between interconnects itself functions as an etching stopper. Thereby, incomplete manufacturing and degradation of reliability, which are caused by the clearance, can be prevented. Moreover, in a conventional technology in which the surface of the metal cap is not nitrided, a via hole in the copper via 4 has reached even the side face of the lower copper interconnect line 2 in a misalignment portion at via etching to cause poor filling (FIG. 6). On the other hand, the nitrided layer 8 functions as an etching stopper in the interconnect structure according to this example. Accordingly, the via hole in the copper via 4 cannot reach the side face of the lower copper interconnect line 2 (FIG. 5), and the contacting (via) reliability can be improved.

It is apparent that the present invention is not limited to the above embodiment, that may be modified and changed without departing from the scope and spirit of the invention.

What is claimed is:

1. A semiconductor device comprising:
a semiconductor substrate;
an insulating layer which has a concave portion and is provided on said semiconductor substrate;
a metal film which includes copper and is embedded in said concave portion; and
a metal cap covering the upper portion of said metal film, wherein
at least the upper portion of said metal cap is nitrided.

2. The semiconductor device according to claim 1,
wherein said concave portion is a trench portion.

3. The semiconductor device according to claim 1,
wherein said concave portion is a hole portion.

4. The semiconductor device according to claim 1,
wherein at least the upper portion of said insulating layer is nitrided.

5. The semiconductor device according to claim 1,
wherein said metal cap is provided in such a way that the upper surface of said metal cap is positioned higher than that of said insulating layer.

6. The semiconductor device according to claim 1,
wherein at least the upper portion of said insulating layer is constituted by hydrophobic insulating material.

7. The semiconductor device according to claim 1,
wherein said insulating layer is a SiOC film, and a SiOCN layer is provided on the surface of said insulating layer.

8. The semiconductor device according to claim 7,
wherein the SiOC film is constituted by porous material.

9. The semiconductor device according to claim 1,
wherein said insulating layer comprises a porous material.

10. The semiconductor device according to claim 1,
wherein said insulating layer has a multilayer structure including a first insulating layer and a second insulating film provided on the upper portion of said first insulating layer, and
the upper surface of the second insulating layer is at the same level as that of said metal, and
said first insulating layer is a porous film and said second insulating layer is a dense film.

11. The semiconductor device according to claim 1,
wherein said metal film forms a metal interconnect line, and
a conductive plug which electrically connects said metal film and another metal film provided thereon is provided on said metal film.

12. The semiconductor device according to claim 9,
wherein said conductive plug and said metal film have approximately the same width.

13. A method of manufacturing a semiconductor device comprising:
forming an insulating layer on a semiconductor substrate;
selectively removing said insulating layer and forming a concave portion;
forming a metal film including copper inside of said a concave portion;
forming a metal cap on the surface of said metal film; and
nitriding the surface of said metal cap and that of said insulating layer.

14. The method of manufacturing a semiconductor device according to claim 13,
wherein said concave potion is trench portion.

15. The semiconductor device according to claim 13,
wherein said concave potion is hole portion.

16. The method of manufacturing a semiconductor device according to claim 13,
wherein said metal cap and said insulating layer are exposed to nitrogen containing plasma to nitride the surface of said metal cap and that of said insulating layer in said step of nitriding.
